(19) United States
(12) Patent Application Publication
(10) Pub. No.: US 2022/0138547 A1
(43) Pub. Date: May 5, 2022

(54) APPARATUS OF ANALOG-NEURON AND METHOD OF CONTROL OF ANALOG-NEURON

(71) Applicants: Toshiba Information Systems (Japan) Corporation, Kawasaki-shi (JP); KABUSHIKI KAISHA TOSHIBA, Tokyo (JP)

(72) Inventors: Manabu Saito, Kawasaki-shi (JP); Junichi Sugino, Kawasaki-shi (JP); Toshimitsu Kitamura, Kawasaki-shi (JP); Yutaka Tamura, Kawasaki-shi (JP); Koji Takahashi, Kawasaki-shi (JP); Takao Marukame, Tokyo (JP)

(73) Assignees: Toshiba Information Systems (Japan) Corporation, Kawasaki-shi (JP); KABUSHIKI KAISHA TOSHIBA, Tokyo (JP)

(21) Appl. No.: 17/513,910

(22) Filed: Oct. 29, 2021

(30) Foreign Application Priority Data
Oct. 29, 2020 (JP) 2020-181807

(51) Int. Cl. G06N 3/063

(52) U.S. Cl. CPC G06N 3/0635

(57) ABSTRACT

An apparatus of analog-neuron includes a synapse circuit for performing arithmetic processing for multiplying an input signal that arrives at an input terminal by a weight value, a synapse output holding means for holding an output signal of the synapse circuit, and a power control unit for controlling whether to supply power at least to the synapse circuit or to stop supplying power in response to whether the input signal has arrived at the input terminal or has been lost.

### CROSS-REFERENCE TO RELATED APPLICATIONS

The present application claims priority under 35 U.S. C. § 119 to Japanese Patent Application No. 2020-181807, filed Oct. 29, 2020. The contents of this application are incorporated herein by reference in their entirety.

### BACKGROUND OF THE INVENTION

### Field of the Invention

The present invention relates to an apparatus of analog-neuron and a control method thereof.

### Discussion of the Background

The conventional apparatus of analog-neuron is always in a full-time operation regardless of whether or not an input signal has arrived. It is also known that activation of a neuron circuit is controlled by a digital clock.

However, the full-time operation as described above means that power is supplied continuously, and consumed wastefully. On the other hand, in the system in which the activation of the neuron is controlled by the digital clock, since there is no constant power consumption other than the leak power in the standby state, although it is superior to the system in the full-time operation, it is irrelevant to the arrival of the input signal, and it is not necessarily possible to suppress wasteful power consumption.

Japanese Patent Application Laid-Open No. 2020-21480 discloses a semiconductor device in which an arithmetic circuit for performing an arithmetic operation of a neural network includes first and second logic circuits, first to fourth transistors, and first and second holding units. In this semiconductor device, the low power supply potential input terminal of the first logic circuit is electrically connected to the first and third transistors, and the low power supply potential input terminal of the second logic circuit is electrically connected to the second and fourth transistors. The first holding unit holds a potential of the second gate of each of the first and fourth transistors as a potential corresponding to the first data. The potential of the second gate of each of the second and third transistors is held by the second holding unit. An ON state or an OFF state of each of the first to fourth transistors is determined by the second data. The difference in input/output time between the signals of the first and second logic circuits is determined according to the first data and the second data.

As described above, the ON state or the OFF state of each of the first to fourth transistors connected to the low power supply potential input terminal of the first logic circuit and the low power supply potential input terminal of the second logic circuit is determined by the second data to reduce power consumption.

Japanese Patent Laid-Open No. 2020-9432 discloses a semiconductor device capable of performing a product-sum operation with low power consumption. Further, it is described that an arithmetic operation of a neural network is performed by the semiconductor device. This semiconductor device has first and second input terminals, first and second output terminals, and a switching circuit, and the switching circuit has first to fourth terminals. The switching circuit has a function of selecting one of the third terminal and the fourth terminal as an electrical connection destination of the first terminal and selecting the other of the third terminal and the fourth terminal as an electrical connection destination of the second terminal in accordance with the first data. The switching circuit includes first and second transistors each including a back gate and has a function of determining a transmission speed of a signal between the first terminal and one of the third terminal and the fourth terminal and a transmission speed of a signal between the second terminal and the other of the third terminal and the fourth terminal in accordance with a potential of the back gate. Note that the potential is determined in accordance with the second data. When signals are input to the first and second terminals, the time difference between the signals output from the third and fourth terminals is determined in accordance with the first data and the second data.

Japanese Patent Application Laid-Open No. 2019-53563 discloses that the arithmetic device 10 according to the embodiment realizes a nonlinear arithmetic operation simulating a neuron with a simple configuration. The arithmetic device 10 performs product-sum operation (multiplication and accumulation) with M coefficients by analog processing, and can generate an output signal by performing sign function processing on a signal corresponding to a multiplication and accumulation value. In particular, the arithmetic device 10 can reduce the dynamic range of the differential voltage input to the comparison unit 36. Therefore, the arithmetic device 10 can execute an arithmetic operation using the comparison unit 36 having a simple configuration. This arithmetic device realizes a neuron with a simple configuration, and is not an invention from the viewpoint of reducing power consumption.

### SUMMARY OF THE INVENTION

The apparatus of analog-neuron according to the present embodiment is an apparatus of analog-neuron including a synapse circuit that performs arithmetic processing of multiplying an input signal that arrives at an input terminal by a weight value, and includes synapse output holding means for holding an output signal of the synapse circuit, and a power control unit that controls whether to supply power at least to the synapse circuit or to stop supplying power in response to whether the input signal has arrived at the input terminal or has been lost.

A control method for an apparatus of analog-neuron according to this embodiment is a method of controlling an apparatus of analog neuron which includes a synapse circuit for performing arithmetic processing for multiplying by a weight value, an input signal that arrives at an input terminal, and synapse output holding means for holding output signals of the synapse circuit, and includes an input signal detection step for detecting whether the input signal has arrived at the input terminal or has been lost, and a power control step for controlling whether to supply power at least to the synapse circuit or to stop supplying power in accordance with a detection result of the input signal detection step.

### BRIEF DESCRIPTION OF THE DRAWINGS

FIG. 1 is a block diagram of an apparatus of analog-neuron according to an embodiment of the present invention.

FIG. 2 is a block diagram showing a configuration of a main part of an apparatus of analog-neuron according to an embodiment of the present invention.

FIG. 3 is a block diagram showing a configuration of a main configuration of an apparatus of analog-neuron according to an embodiment of the present invention.

FIG. 4 is a block diagram showing a main configuration of an apparatus of analog-neuron according to an embodiment of the present invention.

FIG. 5 is a timing chart for explaining the operation of the apparatus of analog-neuron according to the embodiment of the present invention.

### DESCRIPTION OF EMBODIMENTS

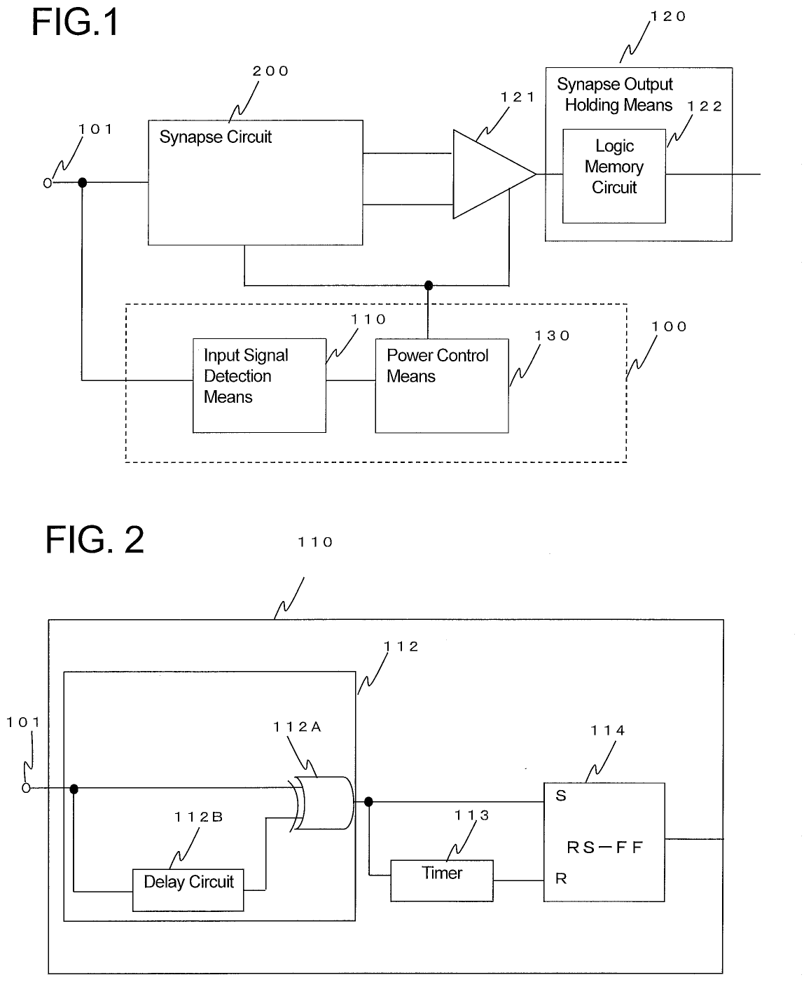

Hereinafter, an apparatus of analog-neuron and a control method of an analog neuron according to an embodiment of the present invention will be described with reference to the accompanying drawings. In the drawings, the same components are denoted by the same reference numerals, and redundant description thereof will be omitted. FIG. 1 shows a block diagram of an apparatus of analog-neuron according to an embodiment of the present invention including a power control unit 100. That is, the apparatus of analog-neuron according to the embodiment of the present invention includes the synapse circuit 200, the power control unit 100, and the synapse output holding means 120 as main components. The synapse circuit 200 performs arithmetic processing of multiplying an input signal arriving at the input terminal 101 by a weight value.

The power control unit 100 controls whether to supply power at least to the synapse circuit 200 or to stop supplying power in response to whether an input signal has arrived at the input terminal 101 or has been lost. The power control unit 100 includes an input signal detection means 110 and a power control means 130.

The input signal detection means 110 detects whether an input signal arrives at the input terminal 101 or is interrupted. Specifically, as shown in FIG. 2, the input signal detection means 110 includes a change detection circuit 112, a timer 113, and an instruction circuit 114. The change detection circuit 112 includes an exclusive OR circuit 112A and a delay circuit 112B for detecting a change in level of signals input to the input terminal 101. The exclusive OR circuit 112A performs an exclusive OR arithmetic operation on signals directly coming from the input terminal 101 and signals delayed from the input terminal 101 via the delay circuit 112B. The delay circuit 112B slightly delays signals arriving from the input terminal 101 and outputs the delayed signals, so that the arrival of signals at the input terminal 101 can be reliably detected by the OR operation of the exclusive OR circuit 112A.

The timer 113 measures a predetermined time TA (FIG. 5) required for the arithmetic operation performed by the synapse circuit 200 from when the change detection circuit 112 detects no change in the signal level. The predetermined time TA may be a time obtained by adding an appropriate margin to a time required for a normal operation performed by the synapse circuit 200. The timer 113 converts the output from 0 to 1, for example, when the counting of the predetermined time TA is completed. The instruction circuit 114 is constituted by, for example, an R-S flip-flop, and the output signals of the exclusive OR circuit 112A are supplied to a set terminal S and the output signals of the timer 113 are supplied to a reset terminal R. The instruction circuit 114, which is an R-S flip-flop, is set when the output of the exclusive OR circuit 112A rises, and is reset when the output of the timer 113 rises (changes from 0 to 1).

The synapse output holding means 120 holds an output signal of the synapse circuit 200. A comparator 121 to digitize the output signal of the synapse circuit 200 is connected between the output side of the synapse circuit 200 and the synapse output holding means 120. The synapse output holding means 120 is constituted by a logic memory circuit 122 connected in series to the comparator 121. The logic memory circuit 122 stores the output signal of the comparator 121. The power control unit 100 controls whether to supply power to the comparator 121 or to stop supplying power in response to whether an input signal arrives at the input terminal 101 or has been lost.

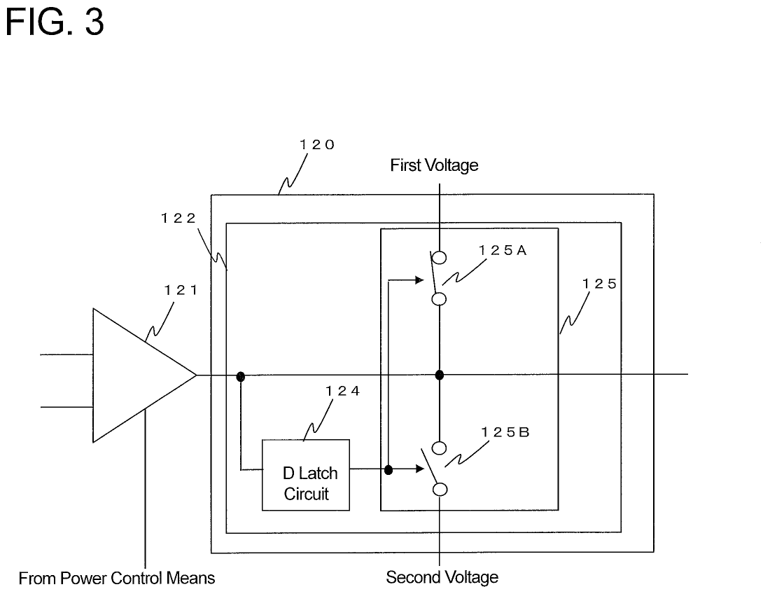

A specific configuration of the logic memory circuit 122 can be, for example, as shown in FIG. 3. The logic memory circuit 122 may include a D latch circuit 124 and a switch circuit 125. The switch circuit 125 has a first switch 125A and a second switch 125B which are connected in series between the power supply voltage and the ground and are opened and closed in a complementary manner, and a connection point of the first switch 125A and the second switch 125B is used as an output terminal. The opening and closing of the first switch 125A and the second switch 125B are controlled by the output of the D latch circuit 124. That is, when the output of the D latch circuit 124 is 1, the first switch 125A is closed and the second switch 125B is opened, and when the output of the D latch circuit 124 is 0, the first switch 125A is opened and the second switch 125B is closed. When the first switch 125A is closed and the second switch 125B is opened, the voltage (first voltage) of the pull-up side power supply is output to the output terminal, and the value thereof becomes 1. When the first switch 125A is open and the second switch 125B is closed, the voltage (second voltage) of the pull-down side power supply is output to the output terminal and its value becomes 0. According to this principle, the output signal of the synapse circuit 200 is digitized by the comparator 121 and stored in the logic memory circuit 122. Even after the input signal input to the input terminal 101 is interrupted and power is not supplied to the synapse circuit 200 and the comparator 121, power continues to be supplied to the logic memory circuit 122, the state of the switch circuit 125 is held, and when the next power supply is started, the state starts from the held state. The D latch circuit 124 employed above is an example of a latch circuit that latches the output signal of the comparator 121, and another latch circuit 124 may be employed.

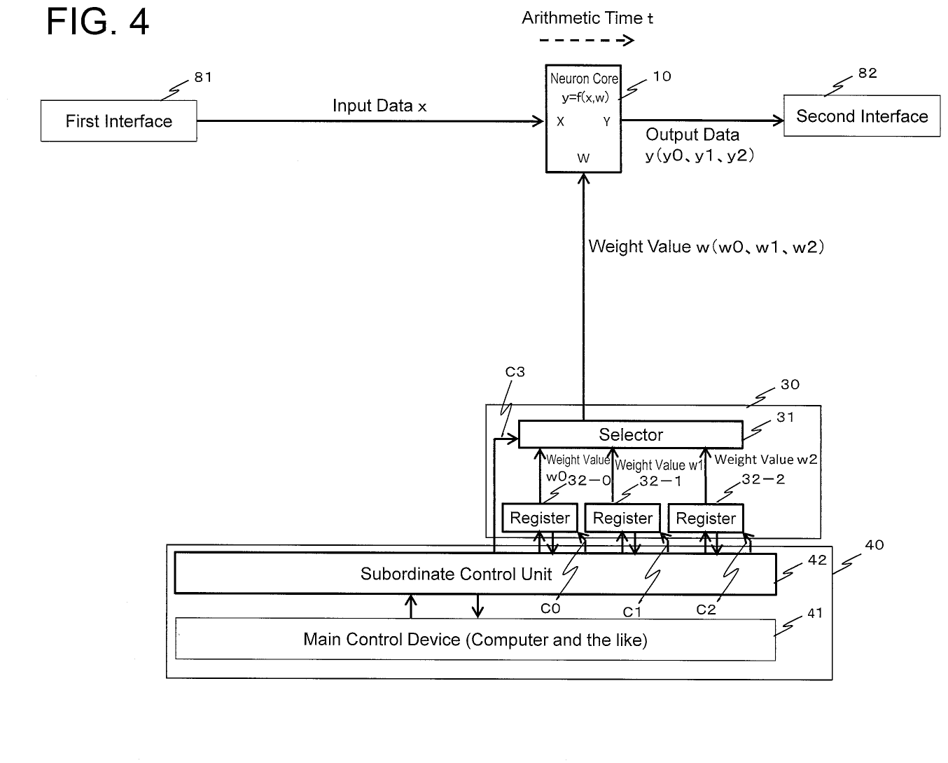

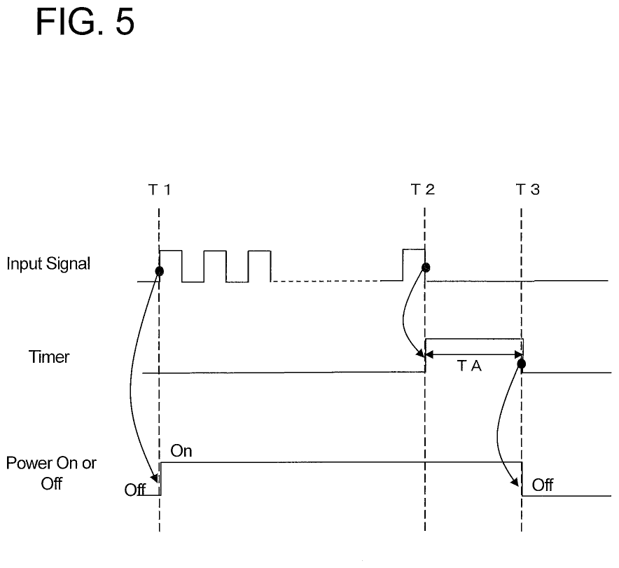

The configuration of the synapse circuit 200 is disclosed in Japanese Patent Application No. 2019-103803 filed by the present inventors, for example, as shown in FIG. 4. The configuration excluding the main control device 41 constitutes a neuron arithmetic apparatus. The neuron may include at least one neuron core unit 10, and may include a weight value supply control unit 30 and a control processing device 40 necessary for the neuron core unit 10. This embodiment shows a configuration in which three parallel neurons can be provided.

In this embodiment, one neuron core unit 10 is provided. The neuron core unit 10 has a data input terminal X, a data output terminal Y, and a weight value input terminal W, performs an analog product-sum operation based on input data x coming from the data input terminal X and a weight value w coming from the weight value input terminal W, and corresponds to the synapse circuit 200 in FIG. 1. The weight value w is any one of weight values w0, w1, and w2 described later. The data input terminal X is connected to the first interface 81, and the input data x arrives via the first interface 81. The neuron core unit 10 performs an analog product-sum operation, and outputs the operation result as output data y from a data output terminal Y. This analog product-sum operation is expressed by y=f (x, w) where f is a function. The output data y is sent out via the second interface 82. The apparatus of analog-neuron can be a configuration to perform power control on the neuron core unit 10 by adding the power control unit 100 to the configuration of the neuron core unit 10.

The selector 31 and the registers 32-0, 32-1, and 32-2 constituting the weight value supply control unit 30 are connected to the weight value input terminal W, and a weight value is supplied from the weight value supply control unit 30. That is, the weight value supply control unit 30 includes a plurality of registers 32-0, 32-1, and 32-2 for holding weight values w0, w1, and w2, respectively, and a selector 31 for selecting any one of the plurality of registers 32-0, 32-1, and 32-2 and opening and closing a path for supplying the selected register as a weight value w to the weight value input terminal W.

A control processing device 40 is connected to the weight value supply control unit 30. The control processing device 40 includes a subordinate control unit 42 and a main control device 41. The main control device 41 comprehensively controls the neurons, and can be configured by a computer or the like. The subordinate control unit 42 is an interface that directly controls the neuron core unit 10 and the weight value supply control unit 30 based on an instruction from the main control device 41, and has functions of a controller, a sequencer, and a command register. Therefore, when instructions and necessary data for executing some serial operations, some parallel operations, or a mixed operation of some serial operations and some parallel operations are given from the main control device 41 to the subordinate control unit 42, the subordinate control unit 42 performs a processing operation so that a final arithmetic operation result can be obtained without intervention of the main control device 41 during a period in which the processing as a neuron is performed. When the weight values w0, w1, and w2 are set in the registers 32-0, 32-1, and 32-2, the subordinate control unit 42 performs control to send control signals to the registers 32-0, 32-1, and 32-2 via the control-signal lines C0, C1, and C2. Further, the subordinate control unit 42 sends control signals to the selector 31 via the control-signal line C3 to select a weight value from any one of the registers 32-0, 32-1, and 32-2, and performs control so as to reach the weight value input terminal W of the neuron core unit 10.

In the neuron configured as described above, required weight values w0, w1, and w2 are set in the registers 32-0, 32-1, and 32-2 under the control of the main control device 41 before the input data x arrives at the data input terminal X of the neuron core unit 10 via the first interface 81. At the timing of the analog product-sum operation of the neuron core unit 10 after the input data x arrives the data input terminal X of neuron core unit 10, the control processing device 40 performs control to supply the weight values w (w0, w1, w2) from the weight value supply control unit 30 in synchronization with this timing.

That is, at the timing of the first analog product-sum operation, the selector 31 is controlled to send the weight value w0 from the register 32-0, at the timing of the second analog product-sum operation, the selector 31 is controlled to send the weight value w1 from the register 32-1, and at the timing of the third analog product-sum operation, the selector 31 is controlled to send the weight value w2 from the register 32-2.

The control processing device 40 processes the output data of each analog product-sum operation from the data output terminal Y as serial output data and/or parallel output data, in addition to control as described above. In the present embodiment, since processing is performed as three parallel output signals, the output signal y0 obtained by the first operation, the output signal y1 obtained by the second operation, and the output signal y2 obtained by the third operation are extracted as output signals y at timings after the respective operations. That is, processing for obtaining three output signals y0, y1, and y2 in a time-division manner is performed, and the output signals are sent to, for example, three paths (not shown) connected to the second interface 82 in a time-division order. According to the present embodiment, although it takes time to obtain the three output signals y0, y1, and y2 in parallel, it is not necessary to use the three neuron core units 10 and the configuration can be simplified. As the configuration of the synapse circuit 200, a configuration disclosed as an embodiment in Japanese Patent Application No. 2019-103803 can be adopted in addition to the configuration of FIG. 4.

The power control means 130 shown in FIG. 1 controls whether to supply power at least to the synapse circuit 200 or power supply is stopped in accordance with the detection result of the input signal detection means 110. Specifically, in the present embodiment, the power control means 130 stops the supply of power to the synapse circuit 200 and the comparator 121 upon receiving an instruction signal from the instruction circuit 114.

The power control unit 100 configured as described above operates according to a procedure shown in a timing chart of FIG. 5. At this time, an input signal detection step T4, it is detected whether or not the input signal has arrived at the input terminal 101. When the input signal starts arriving at the input terminal 101, the output signal of the instruction circuit 114 is shifted from 0 to 1, and upon receiving this, the power control means 130 performs a power control step for starting power supply to the synapse circuit 200 and the comparator 121 (T1).

When the input signal arrives at the input terminal 101 for a while and the arrival of the input signal is stopped at the time T2, a clocking step in which the timer 113 starts clocking is executed. The timer 113 converts the output from 0 to 1, for example, when the counting of the predetermined time TA is completed (T3 in FIG. 5). As a result, an instruction step of changing the output signal of the instruction circuit 114 from 1 to 0 is performed. Upon receiving the output signals from the instruction circuit 114, the power control means 130 stops the power supply to the synapse circuit 200 and the comparator 121 (power control step T1). At this time, since power is continuously supplied to the logic memory circuit 122, the state of the switch circuit 125 is held even after the power supply to the synapse circuit 200 is stopped, and when the next power supply is started, the state is started from the state held in the logic memory circuit 122.

As described above, in the present embodiment, it is possible not only to accurately reduce power consumption in response to whether an input signal arrives at an input terminal or does not arrive at the input terminal, but also to reduce power consumption by appropriately connecting to the next processing because a calculation result remains in the case of subsequent power supply resumption.

In the present embodiment, the synapse circuit 200 and the power control unit 100 are separate from each other. However, the power control unit 100 of the present embodiment may be included in the synapse circuit 200 to form the synapse circuit 200 as a whole. In this case, the synapse circuit 200 has a power control function and a function of storing an output value at the time of power disconnection.

While certain embodiments have been described, these embodiments have been presented by way of example only, and are not intended to limit the scope of the inventions. Indeed, the novel embodiments described herein may be embodied in a variety of other forms, furthermore, various omissions, substitutions and changes in the form of the embodiments described herein may be made without departing from the spirit of the inventions. These embodiments and modifications thereof are included in the scope and spirit of the invention, and are also included in the invention described in the claims and the equivalent scope thereof.

1. An apparatus of analog-neuron comprising a synapse circuit to perform arithmetic processing of multiplying by a weight value, an input signal that arrives at an input terminal, the apparatus comprising:
a synapse output holding means for holding an output signal of the synapse circuit; and
a power control unit to control whether to supply power at least to the synapse circuit or stop supplying of power in response to whether an input signal has arrived at the input terminal or has been lost.

2. The apparatus of analog-neuron according to claim 1,
wherein the power control unit comprises:
an input signal detection means for detecting whether an input signal has arrived at the input terminal or has been lost, and
a power control means for controlling whether power is supplied at least to the synapse circuit or power supply is stopped in accordance with a detection result of the input signal detection means.

3. The apparatus of analog-neuron according to claim 2,
wherein a comparator to digitize the output signal of the synapse circuit is connected between the output side of the synapse circuit and the synapse output holding means, and
wherein the power control unit controls whether to supply power to the synapse circuit and the comparator or to stop the supplying of power in response to whether an input signal has arrived at the input terminal or has been lost.

4. The apparatus of analog-neuron according to claim 3,
wherein the input signal detection means includes:
a change detection circuit to detect presence or absence of a change in the signal level input to the input terminal,
a timer to count a predetermined time required for an operation performed by the synapse circuit after the change detection circuit detects no change in the signal level, and
an instruction circuit to instruct to stop power supply to the synapse circuit and the comparator when time counting by the timer is completed, and
wherein, upon receiving an instruction signal from the instruction circuit, the power control means stops supplying power to the synapse circuit and the comparator.

5. The apparatus of analog-neuron according to claim 3,
wherein the synapse output holding means includes a logic memory circuit to store the output signal of the comparator, and
wherein the power control means controls to supply power to the logic memory circuit when receiving an instruction signal from the instruction circuit,

6. The apparatus of analog-neuron according to claim 5,
wherein the logic memory circuit includes:
a latch circuit to latch an output signal of the comparator, and
a switch circuit having a first switch and a second switch connected in series between a first voltage and a second voltage and having an output terminal at an output point of the first switch and the second switch,
the switch circuit being to open and close the first switch and the second switch in accordance with a logic value stored in the latch circuit.

7. A control method for an apparatus of analog-neuron, the apparatus of analog-neuron comprising a synapse circuit to perform arithmetic processing of multiplying an input signal arriving at an input terminal by a weight value and a synapse output holding means for holding an output signal of the synapse circuit, the method comprising:
an input signal detection step for detecting whether an input signal has arrived at the input terminal or has been lost, and
a power control step for controlling whether to supply power at least to the synapse circuit or stop supplying of power in accordance with a detection result of the input signal detection step.

8. The control method for the apparatus of analog-neuron according to claim 7,
wherein a comparator to digitize the output signal of the synapse circuit is connected between the output side of the synapse circuit and the synapse output holding means in the apparatus of analog-neuron, and
wherein, in the power control step, whether to supply power to the synapse circuit and the comparator or to stop the supplying of power is controlled in response to whether an input signal has arrived at the input terminals or has been lost.

9. The control method for the apparatus of analog-neuron according to claim 8,
wherein the power control step includes:
a change detection step for detecting presence or absence of a change in a level of signals input to the input terminal;
a time counting step for counting a predetermined time required for an operation performed by the synapse circuit from when the change detection step detects presence or absence of a change in a level of signals input to the input terminal; and
an instruction step for instructing to stop power supply to the synapse circuit and the comparator when the time counting step completes counting the predetermined time, and
wherein, in the power control step, the supply of power to the synapse circuit and the comparator is stopped when an instruction by the instruction step is received.

10. The control method for the apparatus of analog-neuron according to claim 9, comprising:
a digitizing step for digitizing the output signal of the synapse circuit by using the comparator; and
a storing step for storing the output signal obtained by the digitizing step in a logic memory circuit logic, and
wherein, in the power control step, control of supplying power to the logic memory is performed circuit even when instruction signals are received in the instruction step.

11. The control method for the apparatus of analog-neuron according to 10,
wherein the logic memory circuit includes:
a latch circuit to latch an output signal of the comparator; and
a switch circuit having a first switch and a second switch connected in series between a first voltage and a second voltage and having an output terminal at an output point of the first switch and the second switch; and
wherein the method further comprises a switch opening and closing step for opening and closing the first switch and the second switch in accordance with the logical value held in the latch circuit.

12. The apparatus of analog-neuron according to claim 4,
wherein the synapse output holding means includes a logic memory circuit to store the output signal of the comparator, and
wherein the power control means controls to supply power to the logic memory circuit when receiving an instruction signal from the instruction circuit.

13. The apparatus of analog-neuron according to claim 12,
wherein the logic memory circuit includes:
a latch circuit to latch an output signal of the comparator, and
a switch circuit having a first switch and a second switch connected in series between a first voltage and a second voltage and having an output terminal at an output point of the first switch and the second switch, the switch circuit being to open and close the first switch and the second switch in accordance with a logic value stored in the latch circuit.
